(19) United States
(12) Patent Application Publication
(10) Pub. No.: US 2025/0012865 A1
(43) Pub. Date: Jan. 9, 2025

(54) BATTERY FULL CHARGE CAPACITY ESTIMATION METHOD AND BATTERY FULL CHARGE CAPACITY ESTIMATION DEVICE

(71) Applicant: Prime Planet Energy & Solutions, Inc., Tokyo (JP)

(72) Inventors: Hiroya MURAO, Himeji-shi (JP); Yasuyuki HARADA, Kakogawa-shi (JP)

(21) Appl. No.: 18/746,039

(22) Filed: Jun. 18, 2024

(30) Foreign Application Priority Data
Jul. 4, 2023 (JP) 2023-109810

(51) Int. Cl. G01R 31/388; G01R 31/367; H01M 10/48

(52) U.S. Cl. CPC G01R 31/388; G01R 31/367; H01M 10/486

(57) ABSTRACT

A battery full charge capacity estimation method includes step (A) of acquiring battery data and processing the acquired data, step (B) of extracting data, and step (C) of estimating a full charge capacity of a battery that is a measurement target. The step (A) includes acquiring battery data including a voltage value, a current value, and a temperature value, and processing the acquired data. The step (B) includes extracting greater than or equal to n data satisfying a predetermined condition from at least one of the data acquired in the step (A) or the data obtained by the processing in the step (A), wherein n is an integer greater than or equal to 3. The step (C) includes estimating a full charge capacity of the battery that is the measurement target based on the data extracted in the step (B).

The present application claims priority from Japanese Patent Application No. 2023-109810 filed on Jul. 4, 2023, which is incorporated by reference herein in its entirety.

### BACKGROUND

The present disclosure relates to a battery full charge capacity estimation method and a battery full charge capacity estimation device.

WO 2012/105492 A discloses a method of detecting a full charge capacity of a battery. The method includes a capacity change detection step, an open circuit voltage detection step, a remaining capacity determination step, a remaining capacity change value calculation step, and a full charge capacity calculation step. In the full charge capacity detection method disclosed in the publication, the full charge capacity of a battery is calculated based on the capacity change value and the remaining capacity change value in a state in which at least one of the capacity change value that is detected in the capacity change detection step, the remaining capacity change value that is detected in the remaining capacity change value calculation step, and the voltage difference between a first open voltage and a second open voltage that are detected in the open circuit voltage detection step is greater than a predetermined set value. It is stated that such a full charge capacity detection method is able to detect the full charge capacity of a battery more accurately.

WO 2012/120620 A discloses a battery status estimation method in which a current value and a terminal voltage value of a battery during battery charge and discharge are measured and the battery status is calculate based on the calculated current value and terminal voltage value. In the battery status estimation method disclosed in the publication, the current and the terminal voltage that are measured during a period from the occurrence of the current change to the lapse of a predetermined time are not used when the change of the measured current value per one second is greater than or equal to a predetermined value. Based on the current values and the terminal voltage values during a battery charge and discharge period other than the just-mentioned period, the battery status is calculated. The battery status estimation method disclosed in the publication calculates at least one of charge rate, deterioration level, and full charge capacity as the battery status. It is stated that such a battery status estimation method is able to more accurately estimate the battery status such as the capacity and deterioration level during discharge.

### SUMMARY

The present inventors intend to improve the estimation accuracy of the full charge capacity of batteries.

A battery full charge capacity estimation method disclosed herein includes step (A) of acquiring battery data and processing the acquired data, step (B) of extracting data, and step (C) of estimating a full charge capacity of a battery that is a measurement target. The step (A) includes acquiring battery data including a voltage value, a current value, and a temperature value that are acquired over time from a battery that is a measurement target, and processing the acquired data. The step (B) includes extracting greater than or equal to n data satisfying a predetermined condition from at least one of the data acquired in the step (A) or the data obtained by the processing in the step (A), wherein n is an integer greater than or equal to 3. The step (C) includes estimating a full charge capacity of the battery that is the measurement target based on the data extracted in the step (B). Such a battery full charge capacity estimation method is able to improve the estimation accuracy of the full charge capacity of batteries.

### BRIEF DESCRIPTION OF THE DRAWINGS

FIG. 1 is a schematic view illustrating a battery system 100.

FIG. 2 is a flowchart illustrating a process flow executed by a controller 40 of a full charge capacity estimation device 20.

FIG. 3 is a circuit diagram illustrating a voltage behavior model 60 for a battery 1.

FIG. 4 is a graph illustrating the relationship between SOC and open circuit voltage OCV.

FIG. 5 is a graph illustrating the relationship between SOCs and current integral values in extracted data D.

FIG. 6 is a flowchart illustrating another process flow executed by the controller 40 of the full charge capacity estimation device 20.

FIG. 7 is a graph illustrating the relationship between SOCs and current integral values in filtered data D1.

FIG. 8 is a flowchart illustrating yet another process flow executed by the controller 40 of the full charge capacity estimation device 20.

FIG. 9 is a graph illustrating the relationship between SOCs and current integral values.

### DETAILED DESCRIPTION

Hereinbelow, embodiments of the technology according to the present disclosure will be described with reference to the drawings. It should be noted, however, that the disclosed embodiments are, of course, not intended to limit the disclosure. The drawings are depicted schematically and do not necessarily accurately depict actual objects. The features and components that exhibit the same effects are designated by the same reference symbols as appropriate, and the description thereof will not be repeated as appropriate.

### Battery System 100

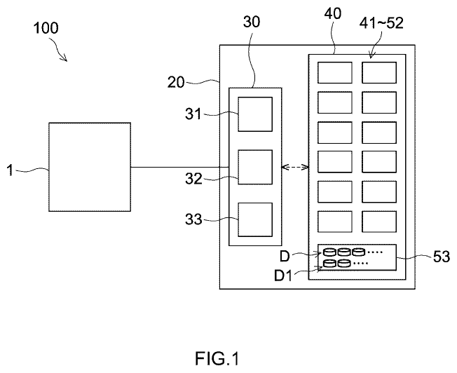

FIG. 1 is a schematic view illustrating a battery system 100. As illustrated in FIG. 1, the battery system 100 includes a battery 1 and a full charge capacity estimation device 20. The battery 1 is connected to an external load, not shown.

In the present description, the term “battery” refers to an electricity storage device that is capable of providing electric energy therefrom. Examples of the battery include secondary batteries, in which repeated charging and discharging are possible by means of migration of charge carriers through an electrolyte between a pair of electrodes (positive electrode and negative electrode), including, for example, lithium-ion secondary batteries. The type of use of the battery is not limited to any particular use. The battery may include battery modules in which a plurality of batteries (cells) are electrically connected to each other. The battery may be, for example, what is called an on-board battery, which serves as a power source of electric vehicles. When the battery is used as an on-board battery, the battery is connected to a charging and discharging device and is charged as appropriate. The battery may be discharged while it is being connected to the charging and discharging device. The battery may be what is called a stationary-purpose battery, which is installed in general households, business sites, or the like. When the battery is used as a stationary-purpose battery, the battery may be connected to a power generation device, a grid power, or the like.

As the battery 1 is charged and discharged, the full charge capacity F of the battery 1 decreases over time. The full charge capacity F refers to the battery capacity that the battery 1 charged to 100% state of charge (SOC), the maximum charge capacity, is capable of providing until it is completely discharged. The full charge capacity estimation device 20 estimates the full charge capacity F of a battery 1.

The full charge capacity estimation device 20 includes a sensor 30 and a controller 40. The sensor 30 includes a voltage sensor 31, a current sensor 32, and a temperature sensor 33. The controller 40 includes an acquisition unit 41, a first calculation unit 42, a first estimation unit 43, a first determination unit 44, a second determination unit 45, a third determination unit 46, a second estimation unit 47, a decision unit 48, a second calculation unit 49, a third estimation unit 50, a fourth determination unit 51, a fifth determination unit 52, and a memory storage unit 53. The controller 40 may be a computer, such as an ECU (electronic control unit) or a circuit board with a built-in microcomputer, for example. The computer performs required functions according to, for example, a predetermined program. Various functions of the computer may be processed by cooperation of software with an arithmetic unit [also referred to as a processor, CPU (central processing unit), or MPU (micro-processing unit)] and a memory storage device (such as a memory and a hard disk) of the computer. In this embodiment, the controller 40 is implemented by an ECU. The various units 41 to 53 of the controller 40 may be implemented by a single processor or a plurality of processors, or may be incorporated in a circuit. The controller 40 is communicably connected to the sensor 30. The memory storage unit 53 may store previously-estimated full charge capacity Fp or the like.

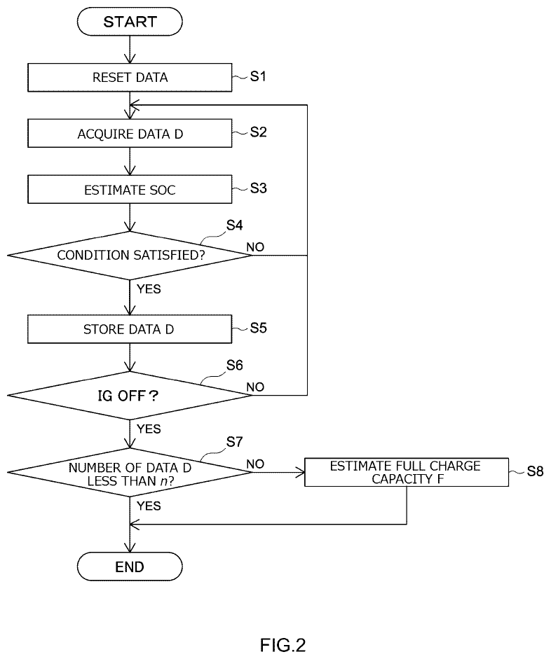

Hereinafter, a method for estimating the full charge capacity F of a battery 1 using the full charge capacity estimation device 20 is described along with the configuration of the full charge capacity estimation device 20. The method of estimating a full charge capacity F of a battery disclosed herein includes step (A) of acquiring data of a battery 1 and processing the acquired data, step (B) of extracting data D satisfying a predetermined condition, and step (C) of estimating the full charge capacity F of the battery 1. FIG. 2 is a flowchart illustrating a process flow executed by the controller 40 of the full charge capacity estimation device 20. FIG. 2 depicts a flow of a method of estimating the full charge capacity F of a battery 1 as an on-board battery.

When an ignition switch of a vehicle is turned on, the process shown in FIG. 2 is started. In step S1, the current integral value and the SOC that were calculated the last time the ignition switch was turned on are reset, or a portion of the stored data is reset.

### Step (A) of Acquiring Data of Battery 1 and Processing Acquired Data

In this embodiment, step (A) includes acquiring data including a current value, a voltage value, and a temperature value of a battery 1 (step S2 in FIG. 2), calculating a current integral value, and obtaining a SOC estimated value (step S3 in FIG. 2).

In step S2, the acquisition unit 41 acquires data of the battery 1. While the vehicle is being activated, including during travel, the acquisition unit 41 acquires the data of the battery 1 during charge and during discharge. The acquisition unit 41 acquires the data while the vehicle is being activated, including the rest period during which electric current is not passed through the battery 1. The data of the battery 1 include current values, voltage values, and temperature values. The acquisition unit 41 acquires the current, voltage, and temperature values detected by the sensor 30 as the data.

The voltage sensor 31 of the sensor 30 detects voltage values of the battery 1. The current sensor 32 detects current values of the battery 1 during charge and during discharge. The temperature sensor 33 detects temperature values of the battery 1. The battery 1 may be a battery module in which a plurality of battery cells are electrically connected to each other. When the battery 1 is a battery module, the temperature sensor 33 and the voltage sensor 31 may include a plurality of temperature sensors and a plurality of voltage sensors, respectively. When the battery 1 is a battery module, one temperature sensor 33 and one voltage sensor 31 may be provided for a plurality of battery cells, or temperature sensors 33 and voltage sensors 31 may be provided respectively for a plurality of battery cells. When one temperature sensor 33 is provided for a plurality of battery cells, the temperature value of each of the battery cells may be estimated by calculation. When the batteries 1 are connected in parallel, one voltage sensor 31 may be provided for the batteries 1 connected in parallel. When the batteries 1 are connected in parallel, a plurality of the current sensors 32 may be provided respectively for the respective batteries 1 connected in parallel. The voltage sensor 31, the current sensor 32, and the temperature sensor 33 respectively detect the current value, the voltage value, and the temperature value of the battery 1 as analog signals.

The data are detected over time from the battery 1 that is a measurement target. Herein, the voltage sensor 31, the current sensor 32, and the temperature sensor 33 may detect the current value, the voltage value, and the temperature value, respectively, at predetermined intervals. The intervals at which the voltage value, the current value, and the temperature value are detected may be, but are not limited to, for example, approximately 0.001 seconds to 1 second (approximately 0.01 seconds to 1 second). The intervals at which the voltage value, the current value, and the temperature value are detected may be set to, for example, regular intervals. The detected analog signals are converted into digital signals by an A/D converter and output to the acquisition unit 41 of the controller 40. The acquisition unit 41 acquires data in association with time instants.

In step S3, the first calculation unit 42 calculates a current integral value from the data acquired by the acquisition unit 41. The first calculation unit 42 accumulates the current values contained in the data to calculate a current integral value. Herein, the current integral value is obtained by the following equation (1):

$$Current integral value = Current integral value accumulated up to the last time \text{} + Δ T \times Current value \qquad ( 1 )$$

Herein, ΔT represents a time between the time instant at which the current value was measured the last time and the time instant at which the current value was measured this time. Also in step S3, the first estimation unit 43 estimates SOC from the acquired data. The first estimation unit 43 obtains an estimated value of SOC based on the data of the battery 1. In this embodiment, the first estimation unit 43 obtains an estimated value of SOC based on the data of the battery 1 and a predetermined voltage behavior model.

The voltage behavior model models the behavior of internal resistance and charge-discharge current of a battery and the behavior of battery voltage using an equivalent circuit. Herein, the SOC of the battery 1 is estimated from the acquired voltage (closed circuit voltage CCV) of the battery 1 based on a voltage behavior model. For the voltage behavior model for estimating SOC, it is possible to use conventionally known battery voltage behavior models, such as CR parallel circuits. Note that the battery voltage behavior model used is not limited to the embodiments described hereinbelow. The battery voltage behavior model may be set as appropriate according to the configuration of the battery 1.

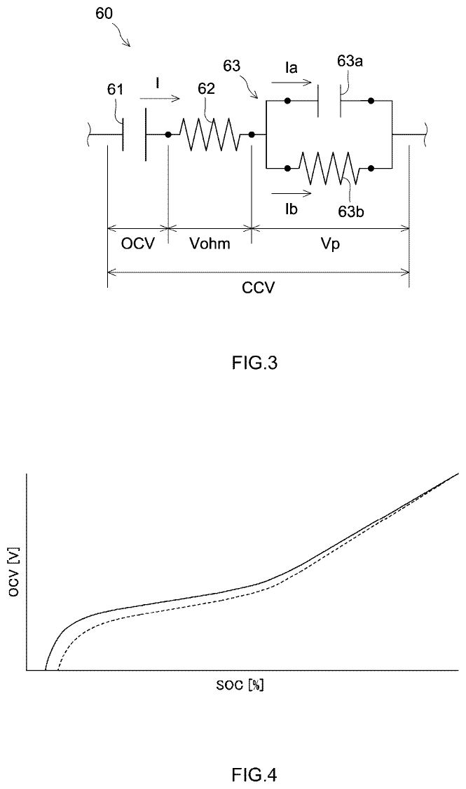

FIG. 3 is a circuit diagram illustrating a voltage behavior model 60 for the battery 1. In FIG. 3, the directions of current I flowing through a voltage source 61, current Ia flowing through a capacitor 63a, and current Ib flowing through an internal resistance 63b are indicated by arrows. As illustrated in FIG. 3, the voltage behavior model 60 includes a voltage source 61, an internal resistance 62, and a CR parallel circuit 63 that are connected in series in that order. The CR parallel circuit 63 is a circuit including a capacitor 63a and an internal resistance 63b that are connected in parallel. The voltage behavior model 60 is able to estimate the open circuit voltage OCV of the voltage source 61.

The open circuit voltage OCV of the voltage source 61 is estimated based on a closed circuit voltage CCV applied to the voltage behavior model 60 and a polarization voltage estimate value (Vp+Vohm) that is the sum of an estimate value Vohm of the voltage drop resulting from the internal resistance 62 and an estimate value Vp of the voltage drop occurring in the CR parallel circuit 63. The open circuit voltage OCV of the voltage source 61 may be estimated, for example, according to the following equation (2):

$$OCV = CCV - Vohm - Vp \qquad ( 2 )$$

Herein, the estimate value Vohm of the voltage drop resulting from the internal resistance 62 may be calculated from the product of a resistance value Rohm of the internal resistance 62 and a current value I flowing through the voltage behavior model 60. The polarization voltage estimate value (Vp+Vohm) may be calculated by adding the product of a resistance value Rp of the internal resistance 63b and a current value Ib flowing through the internal resistance 63b to the product of the resistance value Rohm of the internal resistance 62 and the current value I flowing through the internal resistance 62. It is also possible to use other commonly known electric circuit calculation techniques for obtaining the voltage value of a CR circuit. Thus, the open circuit voltage OCV of the voltage source 61 is estimated.

Note that the resistance value Rohm of the internal resistance 62, which is used to estimate the estimate value Vohm of the voltage drop, and the resistance value Rp of the internal resistance 63b and the capacitance C of the capacitor 63a, which are used to estimate the estimate value Vp of the voltage drop occurring in the CR parallel circuit 63, may vary depending on the SOC and the temperature value of the battery 1. The resistance values Rohm and Rp and the capacitance C may be corrected according to the SOC and the temperature value of the battery 1. For example, a two-dimensional table of temperature value and SOC may be provided for each of the resistance values Rohm and Rp, and the capacitance C. The resistance values Rohm and Rp and the capacitance C may be determined by the temperature values measured by the temperature sensor 33, the SOCs calculated separately, and the two-dimensional table of the temperature values and the SOCs, to be used for estimating the above-described open circuit voltage OCV. This makes it possible to improve the accuracy of estimation of open circuit voltage OCV.

By using the voltage behavior model 60, the open circuit voltage OCV of the battery 1 is estimated based on the voltage values of the battery 1. Subsequently, the SOC of the battery 1 is estimated based on the estimated open circuit voltage OCV. In this embodiment, the SOC of the battery 1 is estimated using an OCV-SOC conversion table that is stored in advance in the controller 40. The OCV-SOC conversion table may be acquired through testing, simulation, theoretical calculation, and the like in advance and stored in the controller 40.

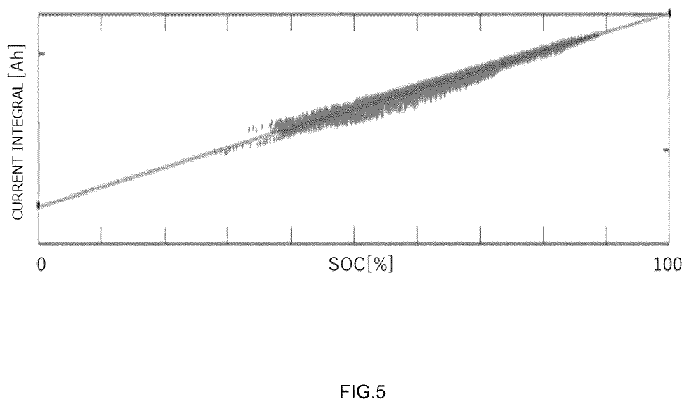

FIG. 4 is a graph illustrating the relationship between SOC and open circuit voltage OCV. In FIG. 4, the relationship between SOC and open circuit voltage OCV is shown in the form of graph. Note that the relationships between SOC and open circuit voltage OCV shown in FIG. 4 are merely schematic representations and do not necessarily reflect the actual relationships. In FIG. 4, the open circuit voltage OCV after charge is indicated by solid line, whereas the open circuit voltage OCV after discharge is indicated by dashed line. As illustrated in FIG. 4, the OCV-SOC conversion table records the open circuit voltage OCV in association with the SOC. In this embodiment, in the OCV-SOC conversion table shown in FIG. 4, the relationship between the SOC and the open circuit voltage OCV after charge and relationship between the SOC and the open circuit voltage OCV after discharge are different. The relationship between SOC and open circuit voltage OCV that is used in estimating SOC may be selected as appropriate according to whether the acquired current values are those acquired during charge or those acquired during discharge. The estimation of SOC of the battery 1 is not limited to such an embodiment, but may use conventionally known techniques, such as the I-V technique in which the open circuit voltage VO is obtained from the plot of current values and CCV. The method of estimating SOC may be decided depending on the usage or the like of the battery 1. For example, when the battery has a low C rate and small fluctuation in current (such as a stationary-purpose battery) and the relationship between SOC and OCV shows a characteristic close to a linear line, the full charge capacity may be estimated from the relationship between voltage values (estimate values of CCV or OCV) and energization time. Likewise, when the battery has a low C rate and small fluctuation in current and the data of the SOC region in which the relationship between SOC and OCV is close to a linear line are used, the full charge capacity may be estimated from the relationship between voltage values and energization time.

### Step (B) of Extracting Data D of Battery 1

Step (B) of extracting data D of the battery 1 includes determining whether or not the data acquired in step (A) satisfy a predetermined condition (step S4 in FIG. 2), and storing data D that satisfy the predetermined condition (step S5 in FIG. 2). For example, step (B) of extracting data D of the battery 1 may include determining whether or not the data acquired over time or obtained by processing in step (A) satisfy a predetermined condition at each time instant, and storing all of or a portion of the data that are acquired or obtained by processing in step (A) at the time instant at which it is determined that they satisfy the predetermined condition.

In step S4, the first determination unit 44 (see FIG. 1) determines whether or not the data acquired by the acquisition unit 41 satisfy a predetermined condition. The predetermined condition may be determined based on a condition under which the estimation accuracy for SOC can be improved. For one example, a description is given for a case in which it is determined whether or not a condition is satisfied based on acquired current values.

In this embodiment, the predetermined condition is set based on an acquired current value and the time instant at which that current value has been acquired. The predetermined condition (hereinafter also referred to as “determination condition”) is set to be that the magnitude of current acquired in step (A) continues for a predetermined time to be less than or equal to a predetermined threshold value. Herein, the term “magnitude of current” refers to the absolute value of a current value, and the absolute values of current values during charge and the absolute values of current values during discharge are used for the determination. Although not limited thereto, the threshold value used for the determination may be set based on a C rate. The threshold value may be set to, for example, a 0.1 C rate, or to a 0.2 C rate. As mentioned previously, the acquired current values are associated with time instants. The determination condition of time may be set to, for example, longer than or equal to 10 seconds. The determination condition of time may be set to, for example, shorter than or equal to 30 seconds. Note that the threshold value for current value and the determination condition of time may be set as appropriate according to the configuration, usage, and the like of the battery 1, and they are not limited to being within the above-described ranges. From the viewpoint of extracting more data D in step (B), the current value may be set higher and the time may be set shorter. From the viewpoint of increasing the accuracy of data D extracted in step (B), the current value may be set lower and the time may be set longer.

Herein, the determination condition is set to be whether or not a current lower than or equal to 0.2 C rate has continued for 20 seconds. If it is determined that a current higher than 0.2 C rate has passed at least any time instant from a certain time instant to 20 seconds before the certain time instant (NO), the first determination unit 44 does not allow the data to be stored in the memory storage unit 53, and the process flow returns to step S2. When a current exceeding a threshold value (0.2 C rate in this embodiment) is detected only in an extremely short time (several samples, for example, 2 samples), the determination condition may be set such that it is not determined that a current higher than a 0.2 C rate has passed, as a countermeasure for inevitable noise or the like. If a current lower than or equal to 0.2 C rate has passed until a time instant 20 seconds before a certain time instant (YES), the data in step (A) at that time instant (such as current values voltage values, temperature values, and SOCs, for example) are stored as data D (step S5 in FIG. 2). The data D are stored in the memory storage unit 53. Herein, the memory storage unit 53 may be, for example, a volatile memory or a nonvolatile memory. When the data D are stored in the memory storage unit 53, the process flow proceeds to step S6.

Note that the determination condition in step S4 is not limited to one condition. For example, it is possible to set different determination conditions according to the time when the determination is made. For example, from the time after the determination condition is turned from unsatisfied to satisfied until the data D are stored for the first time, the determination condition may be set to be whether or not a current of lower than or equal to 0.2 C rate has continued for 10 seconds. When the just-described determination condition continues to be satisfied after this determination condition has been satisfied and the data D has been stored for the first time, the determination condition may be set to be whether or not a current lower than or equal to 0.2 C rate has continued for 5 seconds. However, when the determination condition of whether or not a current of 0.2 C rate has continued for 10 seconds or 5 seconds has not been satisfied even one time, this determination condition may be reset. Thereafter, the determination condition may be set to be whether or not a current lower than or equal to 0.2 C rate has continued for 10 seconds. In some cases, the data to be detected may not be stable at the time when, for example, electric current starts to flow. Because different determination conditions are set according to the time when the determination is made, the data to be acquired may become stable, improving the reliability of the data D.

Note that, during the time when electric current is flowing through the battery 1, an error may occur in the open circuit voltage OCV that is estimated from the detected voltage value. Such an error may occur due to voltage drop. The lower the current flowing in the battery 1, the smaller the error occurring due to voltage drop. As described above, using the data D acquired when the absolute value of the current value is low improves the accuracy of the open circuit voltage OCV, which, as a result, improves the accuracy of the SOC that is estimated based on the open circuit voltage OCV. The improvement of the accuracy of the SOC that is estimated can accordingly improve the accuracy of estimation of the full charge capacity F in step (C).

In step S6, the second determination unit 45 determines whether or not the ignition switch is off. If the ignition switch is not off (NO), the process flow returns to step S2, and subsequently, the acquiring of data and the storing of data D satisfying the predetermined condition are repeated. If the ignition switch is off (YES), the acquisition and extraction of data end, and the process flow proceeds to step S7.

In step S7, the third determination unit 46 determines whether or not the number of the extracted data D (the data D stored in the memory storage unit 53) is less than n. Herein, n is an integer greater than or equal to 3. Although not limited thereto, n may be determined in advance from the viewpoint of statistically estimating the full charge capacity F, from the viewpoint of the amount of memory required for estimating the full charge capacity F, or the like. If the number of the extracted data D is less than n (YES), estimation of the full charge capacity F of the battery 1 is not performed, and the process is terminated. If the number of the extracted data D is not less than n (the number of the extracted data D is greater than or equal to n) (NO), the full charge capacity F of the battery 1 is estimated. It is also possible that additional conditions may be set for the conditions for determining whether the full charge capacity F is estimated or the process is terminated. For example, additional conditions may be set based on the maximum value and the minimum value of SOCs in the stored data D. It is possible that, if the difference between the maximum value and the minimum value of the SOCs in the stored data D is less than a predetermined threshold value even though the number of the extracted data D is not less than n, estimation of the full charge capacity F of the battery 1 may not be performed and the process may be terminated.

### Step (C) of Estimating Full Charge Capacity of Battery 1

Step (C) of estimating the full charge capacity F of a battery 1 involves estimating the full charge capacity F of the battery 1 that is the measurement target based on the data D extracted in step (B) (step S8).

In step S8, the second estimation unit 47 estimates the full charge capacity F of the battery 1 based on the current integral values and the estimated SOCs that are contained in the data D. The second estimation unit 47 may statistically obtain the full charge capacity F from the current integral values and the SOCs contained in the extracted data D. The full charge capacity F may be obtained by, for example, a least squares technique. This may improve the estimation accuracy of the full charge capacity F.

FIG. 5 is a graph illustrating the relationship between SOCs and current integral values in extracted data D. Herein, the full charge capacity F is estimated based on the current integral values and the SOCs in the extracted data D. As illustrated in FIG. 5, the current integral values and the SOCs in the extracted data D are plotted in the graph. The full charge capacity F may be calculated by obtaining the slope of the graph in which the horizontal axis represents SOC (%) and the vertical axis represents current integral value (Ah) and multiplying the obtained slope by 100.

The full charge capacity F estimated in step S8 may be stored in the memory storage unit 53. The stored full charge capacity F may be referenced the next time the full charge capacity F is estimated. The memory storage unit 53 may store the full charge capacity F that is estimated last time or the like.

To the present inventors' knowledge, SOCs are estimated based on the data acquired at 2 points of time at which electric current does not flow in the battery, and the full charge capacity F is estimated. For example, for the batteries mounted in electric vehicles (such as battery electric vehicles (BEVs) and plug-in hybrid electric vehicles (PHEVs)), the data are acquired at such times as before and after the driving, before and after the charging and discharging at a charging and discharging station, during the rest of the electric vehicle, and the like, to estimate the full charge capacity. Then, an attempt is made to improve the estimation accuracy of the full charge capacity by acquiring the data at 2 points of time at which the difference in SOC is great and estimating the full charge capacity. However, for the batteries mounted in the electric vehicles with longer operating hours and shorter resting periods between charge and discharge, such as commercial vehicles, a sufficient resting period may not be available for estimating the SOCs at the 2 points. In this case, the data may not be acquired stably, so the estimation accuracy of the full charge capacity may be reduced. In addition, in the case where the battery is charged immediately after the electric vehicle has stopped, the difference in SOC between the 2 points may be smaller, reducing the estimation accuracy of the full charge capacity. Also, in the case of hybrid electric vehicles (HEVs) in which the battery is charged and discharged repeatedly during travel, the difference in SOC between the 2 points may be smaller, reducing the estimation accuracy of the full charge capacity.

On the other hand, the battery full charge capacity estimation method according to the above-described embodiment includes: step (A) that includes acquiring battery data D including voltage values, current values, and temperature values that are acquired over time from the battery 1 that is a measurement target, and processing the acquired data D; step (B) of extracting greater than or equal to n data D that satisfy a predetermined condition, wherein n is an integer greater than or equal to 3; and step (C) of estimating the full charge capacity F of the battery 1 that is the measurement target based on the data D extracted in the step (B).

Such a full charge capacity estimation method estimates the full charge capacity F based on data D at 3 or more points and therefore is able to improve the accuracy of estimation of the full charge capacity F over the case in which the full charge capacity F is estimated based on the data between 2 points. In addition, among the data obtained over time, the data that satisfy a predetermined condition (a condition that may improve the estimation accuracy of SOC in the above-described embodiment) are extracted and used to estimate the full charge capacity F. The method uses data D that satisfy the above-described determination condition and contain SOC with relatively good accuracy. This improves the estimation accuracy of the full charge capacity F. Moreover, no data that do not satisfy the predetermined condition are extracted. Therefore, the errors caused when estimating the full charge capacity F are reduced in comparison with the case in which the number of data is simply increased to estimate the full charge capacity F. In addition, the memory usage can be kept low in the processing in estimating the full charge capacity F because the amount of data is not too large.

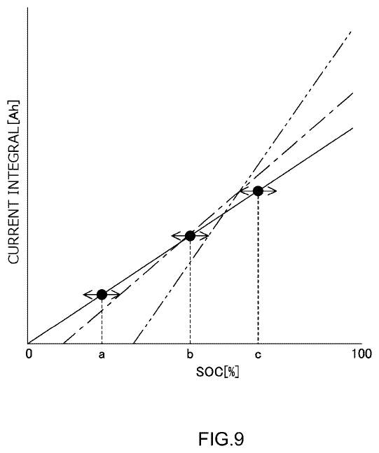

As already mentioned above, if the difference in SOC between the 2 points is small when estimating the full charge capacity F based on the data between the 2 points, the estimation accuracy of the full charge capacity may reduce. FIG. 9 is a graph illustrating the relationship between SOCs and current integral values. FIG. 9 schematically shows the relationships between SOC and current integral values and does not necessarily reflect the actual embodiments. In FIG. 9, the errors of SOCs that can occur are indicated by arrows. Here, the errors of SOCs that can occur are not dependent on SOCs but are constant. FIG. 9 shows respective graphs with the maximum slope for the case where the difference in SOC is small (the dash-dot-dot line in FIG. 9) and for the case where the difference in SOC is large (the dot-dashed line in FIG. 9), along with a graph for the case where there is no error (the solid line in FIG. 9). To the knowledge of the present inventors, the slope of the graph fluctuates more easily when the difference in SOC is smaller (b-a) than when the difference in SOC is greater (c-a). Consequently, the error in the estimate value of the full charge capacity obtained from the slope of the graph may be greater. For example, in the case of hybrid electric vehicles in which the battery is charged and discharged repeatedly during travel, the difference in SOC between the 2 points is unlikely to be large while the vehicle is stopped or in standby. On the other hand, the above-described battery full charge capacity estimation method is able to acquire data D during travel. This enables use of the data D that are acquired in a relatively wide SOC range during travel. As a result, the accuracy of estimation of the full charge capacity F may be improved.

Additionally, in the step (B) of extracting data D of battery 1, the data D may be further filtered when the number of the data D extracted in the step (B) is greater than n. For example, the data D may be further filtered in a descending order of priority based on a predetermined priority. The number of the data D after the filtering may be n or may be a predetermined number that is greater than or equal to n. The following describes an embodiment that includes a process of filtering data D based on priority.

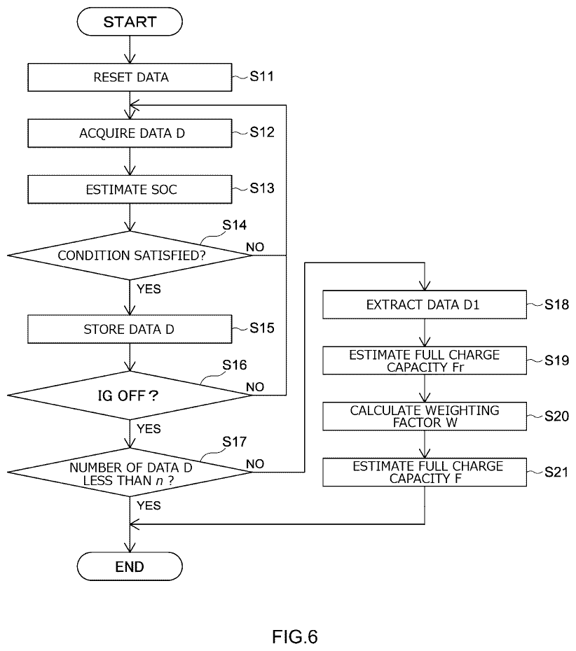

FIG. 6 is a flowchart illustrating a process flow executed by the controller 40 of the full charge capacity estimation device 20. FIG. 6 shows a flowchart illustrating a different process flow shown in FIG. 2. Note that steps S11 to S17 in FIG. 6 are identical to steps S1 to S7 in FIG. 2, respectively, and therefore further detailed description thereof will not be made.

In step S17, the third determination unit 46 determines whether or not the number of the extracted data D is less than n, as in step S7. If the number of the extracted data D is less than n (YES), estimation of the full charge capacity F of the battery 1 is not performed, and the process is terminated. If the number of the extracted data D is greater than n (NO), the process flow proceeds to step S18.

In step S18, the decision unit 48 determines the priority of the data D based on a predetermined priority. The data D are filtered further in a descending order of priority. The predetermined priority may be determined based on a condition under which the estimation accuracy for SOC can be improved. The priority may be determined based on the data D stored in the memory storage unit 53.

In this embodiment, the priority is determined so that the priority is higher when a change in the open circuit voltage is greater relative to a change in the SOC estimate value in the data D stored in the memory storage unit 53. Herein, the priority is determined based on the OCV-SOC conversion table shown in FIG. 4. As described previously, SOC is estimated based on the open circuit voltage OCV estimated from a voltage behavior model and the OCV-SOC conversion table. As illustrated in FIG. 4, the relationship between SOC and open circuit voltage OCV is not linear. The slope of the graph varies depending on the SOC value. For example, the slope of the graph tends to be greater in the higher SOC region of the graph. The greater the slope of the graph is, the less the error in conversion from the open circuit voltage OCV to the SOC is. The less the slope of the graph is, the greater the error in conversion from the open circuit voltage OCV to the SOC is. When the priority is determined so that the priority is higher when a change in the open circuit voltage is greater relative to a change in the SOC estimate value, the error in the SOC estimate value is less, so that the full charge capacity Fr can be estimated with higher accuracy.

The OCV-SOC conversion table may be divided into a plurality of intervals according to SOC. For example, the intervals may be provided for every 1% SOC to 5% SOC. The slope of the graph may be obtained for each divided interval. The priority may be determined so that the data containing SOC in an interval with a greater slope of the graph has a higher priority. Each of the SOCs (or the each of the open circuit voltages OCVs) in the OCV-SOC conversion table may be associated with the slope of the graph. It is possible that the data associated with a higher SOC may have a higher priority.

In addition, the data D1 may be extracted using a least squares technique. The current integral values and the SOCs of respective data D are plotted on a graph, and the least squares line is drawn. The priority may be set so that the data D that are more distant from the least squares line have lower priority. The data D with lower priority may be deleted so as to allow a predetermined number of data D1 specified according to the memory capacity of the controller 40 to remain.

It is also possible that, based on the priority determined by the decision unit 48, a predetermined number of data D1 may be extracted from the data D extracted in the step (B). The number of the data D1 to be extracted may be a predetermined number determined in advance or may be determined as a proportion of the number of the data D extracted in the step (B). The number of the data D1 is not particular limited because, as described above, it is determined according to the memory capacity of the controller 40. The number of the data D1 may be selected from, for example, a number greater than or equal to 3, or a number greater than or equal to 10. The number of the data D1 may be selected from, for example, a number less than or equal to 1000, or a number less than or equal to 500. The number of the data D1 may be, for example, less than or equal to ½ of the number of the data D, or less than or equal to 1/10 of the number of the data D. The number of the data D1 may be determined based on the memory capacity of the controller 40. In step S18, filtering of the data D1 with higher priority is performed, and the process flow proceeds to step S19.

The above-described embodiment has described that the data D extracted in the step (B) are filtered based on priority, embodiments of the disclosure are not limited to such an embodiment. For example, in such cases where all the data D extracted in the step (B) have a higher priority than a predetermined threshold value, all the data D may be used for estimation of the full charge capacity Fr in the step (C). For example, using a greater number of data D that have higher priority may increase the estimation accuracy of the full charge capacity Fr in the step (C).

In step S19, the full charge capacity Fr is estimated based on the data D1 that are filtered from the extracted data D (step (C)). In step S19, the full charge capacity Fr is estimated in the same manner as that in the above-described step S8 (see FIG. 2). Herein, the full charge capacity Fr is obtained statistically from the current integral values and the SOCs contained in the data D1.

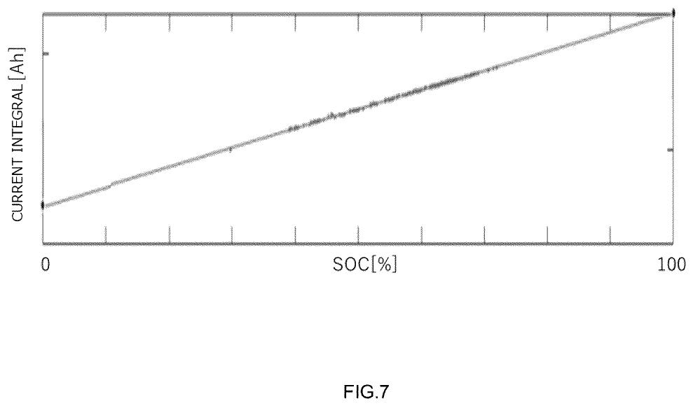

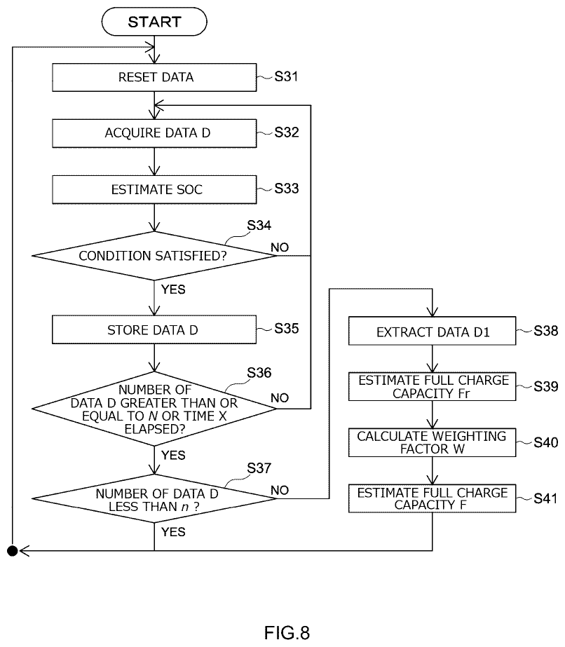

FIG. 7 is a graph illustrating the relationship between SOCs and current integral values in filtered data D1. The data D1 are filtered from the data D based on priority. As illustrated in FIG. 7, the graph in which the current integral values and the SOCs in the data D1 are plotted shows less variation in data points than the graph in which the current integral values and the SOCs in the data D. Thus, use of the data D1 with higher priority in estimating the full charge capacity may improve the accuracy of estimation of the full charge capacity. In addition, filtering the data D based on priority in this way may reduce the memory used for the process of estimating the full charge capacity.

In this embodiment, the battery full charge capacity estimation method further includes step (D) of weighting a last estimated full charge capacity Fp and a full charge capacity Fr estimated in the step (C) according to a predetermined condition, to update the full charge capacity. Herein, the full charge capacity Fr is the full charge capacity Fr that is estimated in step S19 of the step (C).

### Step (D) of Weighting Full Charge Capacity Fp and Full Charge Capacity Fr

Step (D) of weighting the full charge capacity Fp and the full charge capacity Fr includes calculating a weighting factor W (step S20 in FIG. 6) and estimating the full charge capacity F using the weighting factor W (step S21 in FIG. 6).

In step S20, the second calculation unit 49 calculates a weighting factor W according to a predetermined condition. The second calculation unit 49 calculates the weighting factor W based on the filtered data D1 (or the extracted data D). In this embodiment, the predetermined condition in the step (D) is set based on the acquisition time for the data D1 extracted in the step (B), the temperature value, a SOC estimate value, and the number of the data D1 extracted in the step (B). In this embodiment, the weighting factor W is determined based on a factor W1 related to the acquisition time for data D1, a factor W2 related to the temperature value of the battery 1, a factor W3 related to the SOC estimate value of the battery 1, and a factor W4 related to the number of the data D1. Herein, the weighting factor W is calculated according to the following equation (3):

$$W = W 1 \times W 2 \times W 3 \times W 4 \qquad ( 3 )$$

Each of the factors W1 to W4 is set to be greater than or equal to 0 and less than or equal to 1. Therefore, the weighting factor W can be greater than or equal to 0 and less than or equal to 1. Each of the factors W1 to W4 is assigned a value corresponding to the value of each of the parameters. Each of the factors W1 to W4 is assigned a factor corresponding to the value of each of the parameters in the form of a table. Hereinbelow, each of the factors W1 to W4 will be described.

### Factor W1 Related to Acquisition Time for Data D1

The acquisition time for data D1 may be, for example, the time taken to acquire the data D1 that are used for estimating the full charge capacity Fr. The data D acquired in the step (A) are acquired in association with time instants. For this reason, the data D1 used in the step (C) also contain the information of time instants. In this embodiment, the time from which the first acquired data D1, among the data D1 filtered from the data D, is acquired to the time at which the last acquired data D1 is acquired is employed as the acquisition time for data D1. The longer the acquisition time for the data D1 is, the greater the adverse effect on the current integral value becomes, and the shorter the acquisition time for the data D1 is, the less the adverse effect on the current integral value becomes. The factor W1 may be set so as to be greater when the acquisition time for the data D1 is shorter and to be less when the acquisition time for the data D1 is longer.

### Factor W2 Related to Temperature Value of Battery 1

The temperature value of the battery 1 may affect the estimation error in estimating the SOC from the open circuit voltage OCV. When the temperature value of the battery 1 is lower, the internal resistances 62 and 62b (see FIG. 3) are higher, so the estimation error of OCV is greater. As a result, the estimation error of SOC is correspondingly greater. Accordingly, the lower the temperature value of the battery 1 is, the greater the estimation error is. The higher the temperature value of the battery 1 is, the less the estimation error is. The factor W2 may be set so as to be greater when the temperature value of the battery 1 is higher and to be less when the temperature value of the battery 1 is lower.

### Factor W3 Related to SOC Estimate Value of Battery 1

The range of the SOC estimate value of the battery 1 may affect the error in estimating the full charge capacity Fr. For example, when the full charge capacity Fr is estimated using data D1 with a wider SOC range, the adverse effect resulting from the error in each of the data D1 is less on the error caused when estimating the full charge capacity Fr. On the other hand, when the full charge capacity Fr is estimated using data D1 with a narrower SOC range, the adverse effect resulting from the error in each of the data D1 is greater on the error caused when estimating the full charge capacity Fr. The factor W3 may be set according to the difference between the maximum value of the SOC estimate value and the minimum value thereof in the data D1. The factor W3 may be set so as to be greater when the SOC estimate value range (for example, the difference between the maximum value and the minimum value) is wider, and to be less when the SOC estimate value range is narrower.

### Factor W4 Related to the Number of Data D1

The number of the data D1 may affect the estimate value of the full charge capacity Fr. When the full charge capacity Fr is estimated using a least squares technique or the like, the less the number of the data D1 is, the greater the estimation error is, and the greater the number of the data D1 is, the less the estimation error is. The factor W4 may be set so as to be greater when the number of the data D1 is greater and to be less when the number of the data D1 is less.

As described above, the factors W1 to W4 may be determined based on the acquisition time for the data D1, the temperature value, the SOC estimate value, and the number of the data D1, and the weighting factor W may be calculated according to the above equation (3). As described above for each of the factors W1 to W4, the value of the weighting factor W may be greater when the data used have higher reliability of the estimate value of the full charge capacity Fr. However, calculation of the weighting factor W is not limited to such an embodiment. The weighting factor W may be calculated, for example, using a multidimensional table corresponding to the number of parameters contributing to the weighting (4 in the just-described embodiment). The calculation of the weighting factor W based on the multidimensional table may be configured to output one value of the weighting factor W when each of the parameters is input. In addition, the parameters for calculating the weighting factor W is not limited to the acquisition time for the data D1, the temperature value, the SOC estimate value, and the number of the data D1, which are described above. At least one of these parameters may be selected for calculating the weighting factor W. It is also possible to contain other parameters other than the acquisition time for the data D1, the temperature value, the SOC estimate value, and the number of the data D1.

The weighting factor W is calculated in step S20, and subsequently, the full charge capacity F is estimated in step S21.

In step S21, the third estimation unit 50 estimates the full charge capacity F using the weighting factor W calculated in step S20. In this embodiment, the third estimation unit 50 estimates the full charge capacity F based on the full charge capacity Fr estimated in the step (C), the full charge capacity Fp stored in the memory storage unit 53, and the weighting factor W. Herein, the full charge capacity F is estimated according to the following equation (4):

$$F = W \times Fr + ( 1 - W ) \times Fp \qquad ( 4 )$$

In the manner described above, the full charge capacity F is estimated. In this embodiment, the battery full charge capacity estimation method further includes step (D) of weighting a last estimated full charge capacity Fp and a full charge capacity Fr estimated in the step (C) according to a predetermined condition. The use of the last estimated full charge capacity Fp in addition to the full charge capacity Fr estimated in the step (C) for estimating the full charge capacity F may improve the accuracy in estimation of the full charge capacity F.

In the above-described embodiment, the conditions for weighting is set based on the acquisition time for the data D1, the temperature value, the SOC estimate value, and the number of the data D1. These parameters may affect the estimation accuracy of the full charge capacity Fr in the step (C). In other words, these parameters may affect the reliability of the data D1 used in estimating the full charge capacity Fr in the step (C). Herein, the higher the reliability of the data D1 used in estimating the full charge capacity Fr in the step (C) is, the greater the weighting factor Wis. In this case, the weight of the full charge capacity Fr estimated in the step (C) is greater. On the other hand, the lower the reliability of the data D1 is, the greater the weight of the last acquired full charge capacity Fp is. Determining the conditions for weighting based on the acquisition time for the data D1, the temperature value, the SOC estimate value, and the number of the data D1, which may affect the reliability of the data D1, may provide increased accuracy in estimation of the full charge capacity F.

The above-described embodiments have described the cases where the battery 1 is used as a vehicle on-board battery as one example of the embodiments of estimating the full charge capacity F when the external load is stopped. However, the present disclosure is not limited to such embodiments, and it is possible to estimate the full charge capacity F under the condition that the external load is not stopped. For example, it is possible that the determination of whether the ignition switch is on or off in step S6 or step S16 may not be made, but the full charge capacity F may be estimated at the time when a predetermined number of data D are extracted. Moreover, the techniques disclosed herein are also applicable to batteries 1 in which electric current flows constantly. Examples of such batteries 1 include grid powers, power generation devices, and stationary-purpose batteries connected to electrical equipment. Hereinafter, a description is given for a process flow in which the full charge capacity is estimated in a battery 1 that may be used in the form in which electric current flows constantly.

FIG. 8 is a flowchart illustrating a process flow executed by the controller 40 of the full charge capacity estimation device 20. FIG. 8 depicts a flow of a method of estimating the full charge capacity F of a battery 1 as a stationary-purpose battery. In the following description, further detailed description will not be provided for the same processes as those executed in the flows in FIGS. 2 and 6.

The process shown in FIG. 8 may be started at a predetermined time. Although not limited thereto, the process may be started, for example, at a certain time instant every certain time period, such as once every several days, once every week, once every several weeks. Alternatively, the process may be started by the owner's operation of a terminal that manages the battery 1. In step S31, at least a portion of the current integral values and the SOCs that have been calculated before the start of the process may be reset. For example, a certain number of, or a certain proportion of, earlier ones of the current integral values and the SOCs that are stored may be reset.

In steps S32 to S34, the same processes as those of steps S2 to S4 of FIG. 2 are executed. In step S32, data D are acquired. In step S33, current integral values and SOC estimate values are obtained. In step S34, it is determined whether or not the data D satisfy a predetermined condition. In step S35, if the data D satisfy a predetermined condition, the data D are memorized.

In step S36, the fourth determination unit 51 determines whether or not either of the conditions, a condition that the number of the stored data D is a predetermined number N or a condition that a time X has elapsed from step S1, is satisfied. If either of these conditions is satisfied (i.e., if the number of the stored data D reaches greater than or equal to N or if the time X has elapsed from step S1) (YES), the process flow proceeds to step S37. If the time X has not elapsed from step S1 and the number of the stored data D is less than the predetermined number N (NO), the process flow returns to step S32, and subsequently, the acquiring of data and the storing of data D satisfying the predetermined condition are repeated. It should be noted that the number N may be determined in advance from the viewpoint of, for example, the number of data required in statistically estimating the full charge capacity F. The number N is set to a number greater than or equal to the previously-mentioned number n. From the viewpoint of improving the estimation accuracy of the full charge capacity F, it is preferable that the number N be set to as large a number as possible within the constraints of the amount of memory and the amount of computation of the controller 40. However, the number N may be set so that the previously-described weight W1 does not become too low.

In step S7, the fifth determination unit 52 determines whether or not the number of the data D stored is less than n. If the number of the data D stored is less than n (YES), estimation of the full charge capacity F of the battery 1 is not performed, and the series of processes is terminated. In the next process flow, the current integral values and the SOCs that were calculated in the series of processes may be reset, or old data D may be reset (step S31). If the number of the data D stored is not less than n (NO), the process flow proceeds to step S38. If the number of the data D stored is greater than or equal to n, the process of estimating the full charge capacity is started.

In steps S38 to S41, the same processes as those of steps S18 to S21 of FIG. 6 are executed. In step S38, the priority of data D is determined, and the data D are filtered. In step S39, the full charge capacity Fr is estimated in the previously-described manner. In step S40, a weighting factor W is calculated according to a predetermined condition. In step S41, the full charge capacity F is estimated using the weighting factor W. The full charge capacity F is estimated based on the full charge capacity Fr estimated in the step (C), the last estimated full charge capacity Fp, and the weighting factor W. The estimated full charge capacity F is stored in the memory storage unit 53.

Note that in this embodiment, the battery 1 is used in the form in which electric current can flow. This means that electric current continues to flow in the battery 1 even after the estimation of the full charge capacity F in step S41 and also when the process is terminated without estimating the full charge capacity F. Immediately after the series of processes has ended, the process flow may be restarted and the process of estimating the full charge capacity may be restarted.

For the battery 1 that is used in the form in which electric current constantly flows, it is difficult to acquire data at 2 points of time between which the difference in SOC is large, such as before and after charge or before and after discharge, to estimate the full charge capacity, because such a battery does not have a resting period. The technique disclosed herein enables estimation of the full charge capacity even for the battery 1 that is used in the form in which electric current can flows constantly without a resting period. Moreover, the full charge capacities F and Fr are estimated based on highly reliable data (data D satisfying a predetermined condition and data D1 with predetermined high priority), resulting in good accuracy in estimation of the full charge capacities F and Fr.

The extraction of data D, the filtering of data D1, and the like in the step (B) are not limited to the above-described embodiments.

In the above-described embodiments, the condition for extraction of data D in the step (B) is set to be whether or not the magnitude of current that is acquired in step (A) continues for a predetermined time to be less than or equal to a predetermined threshold value (steps S4, S14, and S34). However, the condition for extraction of data D is not limited to such embodiments, but may employ other conditions.

The predetermined condition in steps S4, S14, and S34 may be set on the basis of the estimate value of polarization voltage of the battery 1, which is determined based on the data D acquired in the step (A). For example, the condition may be set on the basis of whether or not the ratio of the polarization estimate value (Vp+Vohm) to the polarization maximum value (Vohm+Vpmax) is less than or equal to a predetermined (for example, less than or equal to 0.1). The condition may be set so that the data D are stored when the polarization estimate value (Vp+Vohm) is less than or equal to the above-described value. Note that Vpmax is the maximum value of the voltage Vp that is applied to the CR parallel circuit 63 under the condition in which the electricity storage amount of the capacitor 63a of FIG. 3 is maximum, which can be acquired in advance. The higher the electric current flowing through the battery 1 in the same direction is, and the longer the electric current flows through the battery 1 in the same direction, the more the polarization of the battery 1 advances. When the time in which a low electric current flows through the battery 1 continues (for example, when an electric current of near 0 A continues to flow for several seconds to several minutes), the polarization gradually decreases. The decrease in polarization varies depending on the type or the like of the battery 1. The controller 40 may store a table in which the level of polarization can be referenced as a numerical value from data D (for example, current value and time). In the step (B), this table may be referred to, to extract data D when the polarization is small. For the polarization estimate value, it is possible to set a threshold value for determining whether or not data D are extracted. Note that the table used here may be acquired in advance according to the type of the battery 1 through testing, simulation, theoretical calculation, and the like, and stored in the controller 40.

For the SOC of the battery 1, the open circuit voltage OCV estimated according to the equation (2) is used, as described previously. The less the polarization voltage estimate value (Vp+Vohm) is, the less the estimation error of the open circuit voltage OCV becomes. For this reason, it is possible to set a threshold value for the polarization voltage estimate value (Vp+Vohm), and to store the data D with which the polarization voltage estimate value (Vp+Vohm) is less than or equal to the threshold value. Extracting the data D with less estimation error of the open circuit voltage OCV may reduce the estimation error of the full charge capacity F.

The predetermined condition in steps S4, S14, and S34 may be set on the basis of the fluctuation range of the current value acquired in the step (A). The fluctuation range of the current value may be determined based on, for example, the difference between the maximum value and the minimum value of the current values contained in the data D that are acquired a plurality of times. The less the fluctuation range of the current value is, the less the estimation error of the open circuit voltage OCV is. In the step (B), it is possible to set a threshold value for the fluctuation range of the current value and to store the data D in which the fluctuation range of the current value is less than or equal to the threshold value. Extracting the data D using the fluctuation range of the current value as the condition may reduce the estimation error of the open circuit voltage OCV, reducing the estimation error of the full charge capacity F.

The predetermined condition in steps S4, S14, and S34 may be set on the basis of a change in SOC that is determined based on the data D acquired in the step (A). The change in SOC may be determined based on, for example, the difference between the SOC estimated based on the acquired data D and the SOC estimated based on the last acquired data. The data D with a smaller change in SOC have less effect on the estimation error of the full charge capacity F. For example, when the current value flowing in the battery 1 is low, for example, the balance of electric current is close to 0, so the change in SOC is small. In the step (B), it is possible to set a threshold value for the change in SOC and to store the data D in which the change in SOC is less than or equal to the threshold value. Extracting the data D using the change in SOC as the condition may reduce the estimation error of the open circuit voltage OCV, reducing the estimation error of the full charge capacity F.

The predetermined condition in steps S4, S14, and S34 may be set based on a variance of the current values that are acquired a plurality of times. When the variance of the current values is small, it is possible to store data D containing the most recently acquired current value.

The predetermined condition in steps S4, S14, and S34 may be set based on a change in the open circuit voltage OCV relative to the SOC estimate value. As described previously, in the graph illustrating the relationship between the SOC and the open circuit voltage OCV, the greater the slope of the graph is, the less the error in conversion from the open circuit voltage OCV to the SOC is. When an open circuit voltage OCV (or a SOC) belonging to an interval with a greater slope of the graph is estimated, the data D may be stored.

In the just-described embodiment, the condition for filtering to the data D1 from the extracted data D in the step (B) is set based on the change of the open circuit voltage relative to the SOC estimate value (steps S18 and S38). However, filtering to the data D1 is not limited to such embodiments, and other conditions may be employed.

The priority in steps S18 and S38 may be determined based on the elapsed time during which the data D are extracted. For example, when a certain period of time has elapsed from the time instant at which data D were extracted for the first time, the condition for determining the priority may be set so as to lower the priority of the data D. When a long time has elapsed from the time instant at which data D were extracted for the first time, the error of the current sensor 32 may have greater adverse effects. This may increase the estimation error of SOC. Although not limited thereto, the elapsed time herein may be set to about 30 minutes to about 1 hour.

The priority in steps S18 and S38 may be determined based on the battery temperature value at the time when data D are extracted. The temperature value of the battery 1 may affect the estimation error in estimating the SOC from the open circuit voltage OCV. The lower the temperature value of the battery 1 is, the greater the estimation error is. The higher the temperature value of the battery 1 is, the less the estimation error is. For example, the condition for determining the priority may be set so as to lower the priority of the data D with a lower temperature value when the variation in the temperature values contained in the data D is greater.

The condition for determining the priority may be selected from one of the above-described conditions, or alternatively, a plurality of the above-described conditions may be combined to determine the priority.

Note that estimation of the open circuit voltage OCV, the SOC, the full charge capacity F, and so forth may be corrected as appropriate. For example, the equation (2) for estimating the open circuit voltage OCV may contain a term for correcting voltage hysteresis. The magnitude of hysteresis may vary depending on the SOC. It is possible that the data containing greater hysteresis may be processed so as to have a less contribution level to estimation of the full charge capacity.

The data containing greater hysteresis may be corrected so as to produce a less weighting factor W when calculating the weighting factor W. When the numbers of the data D and D1 are large and the data D and D1 contain a wide SOC range but a small current integral value, the data may be corrected so as to produce a greater weighting factor W when calculating the weighting factor W. At this time, the battery 1 is charged and discharged in a well-balanced manner, so the estimation error of the full charge capacity may be reduced.

When estimating the SOC based on the open circuit voltage OCV and the current integral value, reliability may be obtained for each of the data D and weighting may be performed according to the reliability to estimate the SOC. Although not limited thereto, the data D may be processed so as to increase the reliability, for example, when the current value is low, when the temperature value of the battery 1 is high, and when the slope of the open circuit voltage OCV-SOC graph is great. For the current value, the reliability may be determined based on, not an instantaneous current for such as 0.1 seconds, but a current for about 10 seconds to about 300 seconds.

When estimating the full charge capacity Fr, a confidence interval for data D and D1 may be obtained to determine the weighting factor W according to a confidence interval range (i.e., the difference between the upper limit and the lower limit of the confidence interval). The weighting factor W may be set so as to be greater when the confidence interval range is narrower.

Various embodiments of the technology according to the present disclosure have been described hereinabove. Unless specifically stated otherwise, the embodiments described herein do not limit the scope of the present disclosure. It should be noted that various other modifications and alterations may be possible in the embodiments of the technology disclosed herein. In addition, the features, structures, or steps described herein may be omitted as appropriate, or may be combined in any suitable combinations, unless specifically stated otherwise. In addition, the present description includes the disclosure as set forth in the following items.

### Item 1:

A battery full charge capacity estimation method including:
step (A) including acquiring battery data including a voltage value, a current value, and a temperature value, the battery data acquired over time from a battery that is a measurement target, and processing the acquired data;
step (B) of extracting greater than or equal to n data satisfying a predetermined condition, from at least one of data acquired in the step (A) and data obtained by the processing in the step (A), wherein n is an integer greater than or equal to 3; and
step (C) of estimating a full charge capacity of the battery that is the measurement target based on the data extracted in the step (B).

### Item 2:

The battery full charge capacity estimation method according to item 1, wherein the predetermined condition in the step (B) includes a magnitude of the current value acquired in the step (A) that continues for a predetermined time to be less than or equal to a predetermined threshold value.

### Item 3:

The battery full charge capacity estimation method according to item 1 or 2, wherein the step (B) includes filtering the data extracted in the step (B) based on a predetermined priority in a descending order of priority when the number of the data extracted in the step (B) is greater than n.

### Item 4:

The battery full charge capacity estimation method according to item 3, wherein:
the step (A) includes processing the acquired data based on a predetermined battery voltage behavior model to obtain an open circuit voltage and a SOC estimate value; and
the priority is determined so that the priority is higher when a change in the open circuit voltage is greater relative to a change in the SOC estimate value.

### Item 5:

The battery full charge capacity estimation method according to any one of items 1 to 4, wherein:

a full charge capacity that is estimated last time is memorized; and
the method further comprises step (D) of weighting the last estimated full charge capacity and the full charge capacity estimated in the step (C) according to a predetermined condition to update the full charge capacity.

### Item 6:

The battery full charge capacity estimation method according to item 5, wherein:
the predetermined condition in the step (D) is set based on at least one of an acquisition time for the data extracted in the step (B), the temperature value, a SOC estimate value, and a number of the data extracted in the step (B); and
the SOC estimate value is estimated based on the data acquired in the step (A) and a predetermined battery voltage behavior model.

### Item 7:

The battery full charge capacity estimation method according to any one of items 1 to 6, wherein:
the step (A) includes:
   integrating the current value to calculate a current integral value up to each time instant for the battery data acquired over time; and
   obtaining a SOC estimate value based on the battery data and a predetermined voltage behavior model.

### Item 8:

The battery full charge capacity estimation method according to item 7, wherein the full charge capacity of the battery that is the measurement target is estimated based on the current integral value and the SOC estimate value.

### Item 9:

The battery full charge capacity estimation method according to item 1, wherein the predetermined condition in the step (B) is determined based on a polarization estimate value of the battery, the estimate value obtained by processing the data acquired in the step (A).

### Item 10:

The battery full charge capacity estimation method according to item 1, wherein the predetermined condition in the step (B) is determined based on a fluctuation range of the current value acquired in the step (A).

### Item 11:

The battery full charge capacity estimation method according to item 1, wherein the predetermined condition in the step (B) is determined based on a change in SOC that is obtained by processing the data acquired in the step (A).

### Item 12:

A battery full charge capacity estimation device including:
one or more sensors; and
a controller,
the one or more sensors including:
   a voltage sensor;
   a current sensor; and
   a temperature sensor, wherein:
the controller is configured to execute:
   a process including acquiring battery data including a voltage value, a current value, and a temperature value, the battery data acquired over time from a battery that is a measurement target, and processing the acquired data;
   a process of extracting greater than or equal to n data satisfying a predetermined condition, from at least one of data that are acquired and data that are obtained by the processing, wherein n is an integer greater than or equal to 3; and
   a process of estimating a full charge capacity of the battery that is the measurement target based on the extracted data.

### Item 13:

The battery full charge capacity estimation device according to item 12, wherein the controller is configured to execute a process of filtering the extracted data based on a predetermined priority in a descending order of priority when the number of the extracted data is greater than n.

### Item 14:

The battery full charge capacity estimation device according to item 12 or 13, wherein:
the controller stores a full charge capacity that is estimated last time; and
the controller is configured to execute a process of weighting the full charge capacity estimated last time and the full charge capacity estimated based on the extracted data according to a predetermined condition.

What is claimed is:

1. A battery full charge capacity estimation method comprising:
step (A) including acquiring battery data including a voltage value, a current value, and a temperature value, the battery data acquired over time from a battery that is a measurement target, and processing the acquired data;
step (B) of extracting greater than or equal to n data satisfying a predetermined condition, from at least one of data acquired in the step (A) and data obtained by the processing in the step (A), wherein n is an integer greater than or equal to 3; and
step (C) of estimating a full charge capacity of the battery that is the measurement target based on the data extracted in the step (B).

2. The battery full charge capacity estimation method according to claim 1, wherein the predetermined condition in the step (B) includes a magnitude of the current value acquired in the step (A) that continues for a predetermined time to be less than or equal to a predetermined threshold value.

3. The battery full charge capacity estimation method according to claim 1, wherein the step (B) includes filtering the data extracted in the step (B) based on a predetermined priority in a descending order of priority when the number of the data extracted in the step (B) is greater than n.

4. The battery full charge capacity estimation method according to claim 3, wherein:
the step (A) includes processing the acquired data based on a predetermined battery voltage behavior model to obtain an open circuit voltage and a SOC estimate value; and
the priority is determined so that the priority is higher when a change in the open circuit voltage is greater relative to a change in the SOC estimate value.

5. The battery full charge capacity estimation method according to claim 1, wherein:
a full charge capacity that is estimated last time is memorized; and
the method further comprises step (D) of weighting the last estimated full charge capacity and the full charge capacity estimated in the step (C) according to a predetermined condition to update the full charge capacity.

6. The battery full charge capacity estimation method according to claim 5, wherein:
the predetermined condition in the step (D) is set based on at least one of an acquisition time for the data extracted in the step (B), the temperature value, a SOC estimate value, and a number of the data extracted in the step (B); and
the SOC estimate value is estimated based on the data acquired in the step (A) and a predetermined battery voltage behavior model.

7. The battery full charge capacity estimation method according to claim 1, wherein:
the step (A) includes:
integrating the current value to calculate a current integral value up to each time instant for the battery data acquired over time; and
obtaining a SOC estimate value based on the battery data and a predetermined voltage behavior model.

8. The battery full charge capacity estimation method according to claim 7, wherein the full charge capacity of the battery that is the measurement target is estimated based on the current integral value and the SOC estimate value.

9. The battery full charge capacity estimation method according to claim 1, wherein the predetermined condition in the step (B) is determined based on a polarization estimate value of the battery, the estimate value obtained by processing the data acquired in the step (A).

10. The battery full charge capacity estimation method according to claim 1, wherein the predetermined condition in the step (B) is determined based on a fluctuation range of the current value acquired in the step (A).

11. The battery full charge capacity estimation method according to claim 1, wherein the predetermined condition in the step (B) is determined based on a change in SOC that is obtained by processing the data acquired in the step (A).

12. A battery full charge capacity estimation device comprising:
one or more sensors; and
a controller,
the one or more sensors including:
a voltage sensor;
a current sensor; and
a temperature sensor, wherein:
the controller is configured to execute:
a process including acquiring battery data including a voltage value, a current value, and a temperature value, the battery data acquired over time from a battery that is a measurement target, and processing the acquired data;
a process of extracting greater than or equal to n data satisfying a predetermined condition, from at least one of data that are acquired and data that are obtained by the processing, wherein n is an integer greater than or equal to 3; and
a process of estimating a full charge capacity of the battery that is the measurement target based on the extracted data.

13. The battery full charge capacity estimation device according to claim 12, wherein the controller is configured to execute a process of filtering the extracted data based on a predetermined priority in a descending order of priority when the number of the extracted data is greater than n.

14. The battery full charge capacity estimation device according to claim 12, wherein:
the controller stores a full charge capacity that is estimated last time; and
the controller is configured to execute a process of weighting the full charge capacity estimated last time and the full charge capacity estimated based on the extracted data according to a predetermined condition.
